(19) United States
(12) Patent Application Publication
(10) Pub. No.: US 2007/0178681 A1
(43) Pub. Date: Aug. 2, 2007

(54) SEMICONDUCTOR DEVICE HAVING A PLURALITY OF METAL LAYERS DEPOSITED THEREON

(75) Inventors: Young-su CHUNG, Yongin-si (KR); Sung-kee HAN, Yongin-si (KR); Hyung-suk JUNG, Yongin-si (KR); Hyung-ik LEE, Yongin-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD.,, Suwon-si (KR)

(21) Appl. No.: 11/621,589

(22) Filed: Jan. 10, 2007

(30) Foreign Application Priority Data
Feb. 2, 2006 (KR) 1020060010123

(51) Int. Cl. H01L 21/20

(52) U.S. Cl. 438/584

(57) ABSTRACT

A semiconductor device has a plurality of stacked metal layers. The semiconductor device includes a substrate, a gate oxide layer deposited on the substrate and formed from a high-k dielectric material, a first metal layer deposited on the gate oxide layer and formed from a nitride of a metal of the high-k dielectric material of the gate oxide layer, a second metal layer deposited on the first metal layer, a third metal layer deposited on the second metal layer, and a material layer deposited on the third metal layer, wherein the material layer taken together with the first, second and third metal layers forms a gate electrode. Because any chemical reaction between the gate oxide layer and the metal layer can be controlled, deterioration of the capacitance equivalent oxide thickness) and leakage of current are prevented, and a semiconductor device having improved insulation can be provided.

This application claims priority to Korean Patent Application No. 2006-0010123, filed on Feb. 2, 2006, and all the benefits accruing therefrom under 35 U.S.C. §119, the contents of which are herein incorporated by reference in its entirety.

### BACKGROUND OF THE INVENTION

1. Field of the Invention

The present invention relates to a semiconductor device and, more particularly, to a semiconductor device which has a plurality of metal layers deposited thereon to improve insulation.

2. Description of the Related Art

One type of semiconductor device is a metal oxide semiconductor (MOS), which includes a semiconductor substrate having gate oxide layers and metal layers deposited on the substrate in turn. There are also complementary metal oxide semiconductors (CMOS) that make use of pairs of complementary n-channel MOS (nMOS) and p-channel MOS (pMOS) transistors. Because semiconductor devices such as CMOS consume low amounts of power, they are widely used in electronics and are actively researched. A fabrication method using a metal inserted polycrystalline Si stack (MIPS) structure has been widely used, wherein metal layers and polycrystalline silicon (poly-Si) are stacked on the gate oxide layer to form a gate electrode of the semiconductor device.

FIG. 1 is a cross-sectional view of an existing semiconductor device. Referring to FIG. 1, a gate oxide layer 12 is deposited on a semiconductor substrate 11, and a metal layer 13 is deposited on the gate oxide layer 12. A gate electrode is formed into a MIPS structure when a layer of poly-Si 14 is stacked on the metal layer 13. The semiconductor substrate 11 is formed of silicon, the gate oxide layer 12 is formed of hafnium oxide (HfO₂), and the metal layer 13 is formed of tantalum nitride (TaN). There is a chemical reaction between the two types of material on the gate oxide layer 12 and the metal layer 13; that is, there is a chemical reaction between HfO₂ and TaN, and an interface layer is produced. The thickness of the interface layer is expressed by a capacitance equivalent oxide thickness (CET) characteristic. When the thickness of the interface layer between the gate oxide layer 12 and the metal layer 13 increases, the CET characteristic deteriorates. However, when the thickness of the gate oxide layer 12 is decreased, capacitance of the gate oxide layer 12 is decreased, and tunneling of carriers such as electron holes increases. Accordingly, a leakage current is generated and the insulation of the semiconductor device degrades.

### BRIEF SUMMARY OF THE INVENTION

Therefore, an aspect of the present invention includes providing a semiconductor device, having an improved CET and insulation, which has a gate electrode fabricated by stacking a plurality of metal layers on each other, with the metal layer that contacts the gate oxide layer being formed from a material having a common metal element as the material of the gate oxide layer.

According to an exemplary embodiment of the present invention, a semiconductor device includes a substrate; a gate oxide layer deposited on the substrate, and formed from a high-k dielectric material; a first metal layer deposited on the gate oxide layer, and formed from a nitride of a metal of the high-k dielectric material of the gate oxide layer; a second metal layer deposited on the first metal layer; a third metal layer deposited on the second metal layer; and a material layer deposited on the third metal layer, wherein the material layer taken together with the first, second and third metal layers forms a gate electrode.

According to another exemplary embodiment, a method for making the semiconductor device includes depositing a gate oxide layer comprising a high-k dielectric on a substrate; depositing a first metal layer on the gate oxide layer, wherein the first metal layer is formed from a nitride of a metal of the high-k dielectric material of the gate oxide layer; depositing at least one more metal layer on the first metal layer; and depositing a material layer on the at least one more metal layer, wherein the material layer taken together with the all of the metal layers forms a gate electrode.

The gate oxide layer may be formed from SiO₂ and a material having a dielectric constant greater than or equal to about 3.9.

The gate oxide layer material may also include a nitride.

The first metal layer may be formed from one or more elements selected from the group consisting of HfN, ZrN, AlN, TiN, LaN, YN, GdN, and TaN.

The first metal layer material may also include an Si-containing composition or an Al-containing composition.

The second metal layer may be formed from a metallic nitride comprising one or more elements selected from the group consisting of W, Mo, Ti, Ta, Al, Hf, La, Gd, Y, Pr, Dy, Er, and Zr.

The second metal layer material may also include an Si-containing composition or an Al-containing composition.

The third metal layer may be formed from a metal or a metallic nitride comprising one or more elements selected from the group consisting of W, Mo, Ti, Ta, Al, Hf, and Zr.

The third metal layer material may also include an Si-containing composition or an Al-containing composition.

The gate oxide layer may be formed from HfSiO, and the first metal layer may be formed from HfN.

The second metal layer may be formed from AlN, and the third metal layer may be formed from TaN.

The first metal layer may have an average thickness of about 1 to about 100 Angstroms

[symbol]

The second metal layer may have an average thickness of about 1 to about 100 Å.

The third metal layer may have an average thickness of about 1 to about 1000 Å.

The material layer deposited on the third metal layer may be formed from one of polycrystalline Si, W, WN, and WSi.

### BRIEF DESCRIPTION OF THE DRAWINGS

The above aspects and features of the present invention will be more clearly understood from the following detailed description taken in conjunction with the accompanying drawings, in which:

FIG. 1 is a cross-sectional view of an existing semiconductor device;

FIG. 2 is a cross-sectional view of an exemplary embodiment of a semiconductor device according to the present invention;

FIG. 3A is a graphical representation of the C-V characteristics of various semiconductor devices;

FIG. 3B is a graphical representation of the leakage current density-voltage characteristics of various semiconductor devices; and

FIG. 3C is a graphical representation of the leakage c-current densities and CETs of various semiconductor devices at certain voltages.

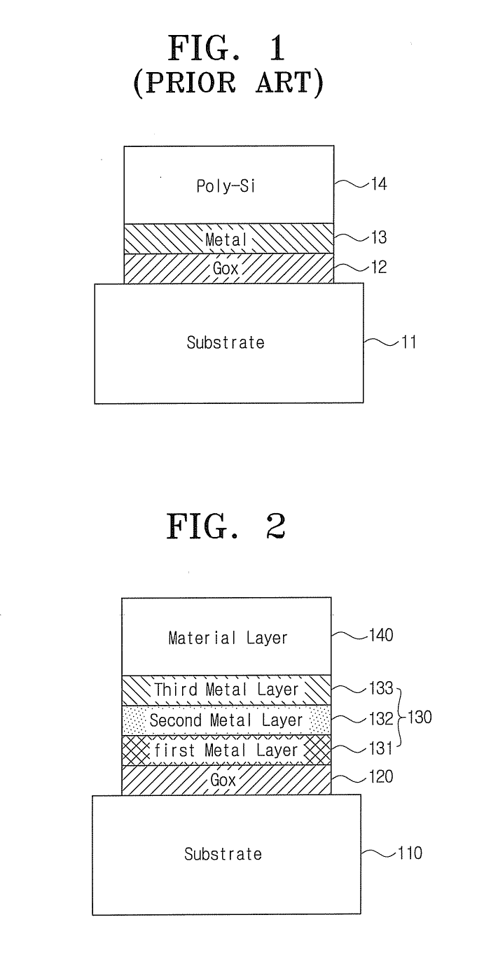

### DETAILED DESCRIPTION OF THE INVENTION

The present invention will now be described more fully hereinafter with reference to the accompanying drawings, in which exemplary embodiments of the invention are shown. The invention may, however, be embodied in many different forms and should not be construed as limited to the exemplary embodiments set forth herein. Rather these embodiments are provided so that this disclosure will be thorough and complete, and will fully convey the scope of the invention to those skilled in the art. In the drawings, the size and relative sizes of layers and regions may be exaggerated for clarity, and like reference numerals refer to like elements throughout.

It will be understood that when an element or layer is referred to as being “on” or “connected to” another element or layer, the element or layer can be directly on or connected to the other element or layer or intervening elements or layers that are present therebetween. In contrast, when an element is referred to as being “directly on” or “directly connected to” another element or layer, there are no intervening elements or layers present. As used herein, the term “and/or” includes any and all combinations of one or more of the associated listed items.

The terminology used herein is for the purposes of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Also, well-known functions or constructions are not described in detail since they would obscure the invention in unnecessary detail.

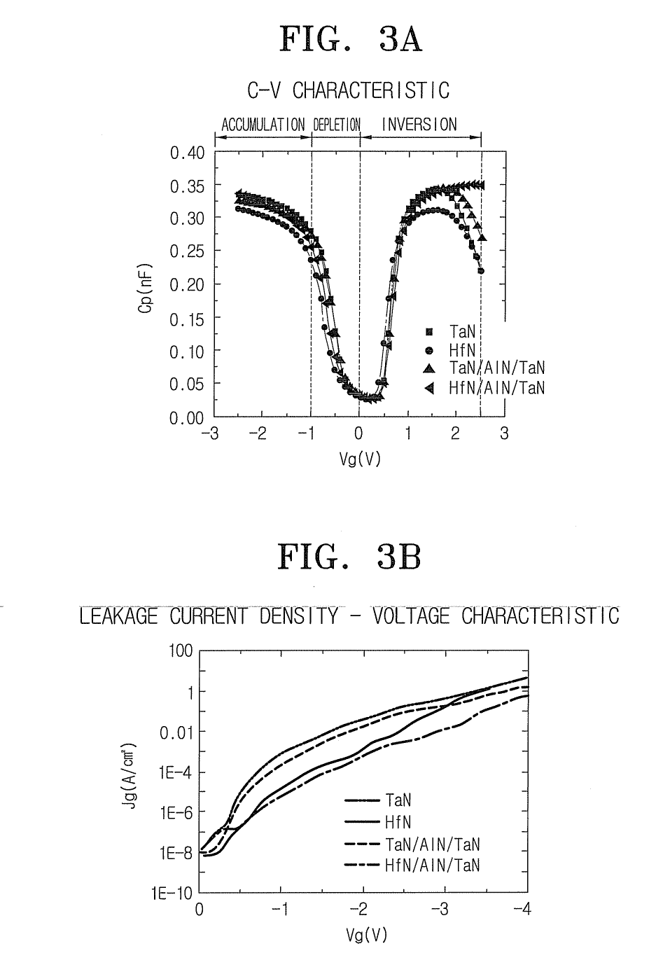

Referring now to FIG. 2, an exemplary embodiment of a semiconductor device according to the present invention is shown. The semiconductor device generally includes a substrate 110, a gate oxide layer 120, a plurality of metal layers 130, and a material layer 140.

The substrate 110 may be a silicon (Si) substrate.

The gate oxide layer 120 protects the substrate 110, and electrically isolates the substrate 110 from the upper components. The gate oxide layer 120 may be formed from SiO₂ and/or a material having a high dielectric constant (hereafter “high-k dielectric material”). As used herein, a high-k dielectric material has a dielectric constant (k) greater than or equal to about 3.9. Exemplary materials that have dielectric constants greater than or equal to about 3.9 are compositions that include hafnium (Hf), zirconium (Zr), aluminum (Al), titanium (Ti), lanthanum (La), yttrium (Y), gadolinium (Gd), and tantalum (Ta). The gate oxide layer 120 may include SiO₂ and a metal oxide containing one or more of the above-mentioned high-k materials. The gate oxide layer 120 may include a combination of materials stated above and/or a nitride. The gate oxide layer 120 may be deposited using membrane processing techniques such as chemical vapor deposition (CVD), physical vapor deposition (PVD), atomic layer deposition (ALD), and epitaxy.

The metal layers 130 may include a first metal layer 131, a second metal layer 132, and a third metal layer 133, and may be used as a gate electrode when taken together with the material layer 140. More specifically, the first metal layer 131 is deposited on the gate oxide layer 120, and is formed from a material having a common element as the material of the gate oxide layer 120 (e.g., the high-k dielectric material of the gate oxide layer 120). For example, if the gate oxide layer 120 is formed from a hafnium silicon oxide layer (HfSiO), the first metal layer 131 may be formed from a material having hafnium and/or silicon, such as hafnium nitride (HfN). Accordingly, the formation of ail interface layer can be reduced by controlling the type of chemical reaction that can occur between the gate oxide layer 120 and the first metal layer 131. With the thickness of the interface layer being reduced, the capacitance equivalent oxide thickness (CET) characteristic improves, and there is less leakage of current in the semiconductor device.

The first metal layer 131 may comprise one or more selected from the group consisting of zirconium nitride (ZrN), aluminum nitride (AlN), titanium nitride (TiN), lanthanum nitride (LaN), yttrium nitride (YN), gadolinium nitride (GdN) and tantalum nitride (TaN). Alternatively, the first metal layer 131 may comprise one or more selected from the group consisting of zirconium nitride (ZrN), aluminum nitride (AlN), titanium nitride (TiN), lanthanum nitride (LaN), yttrium nitride (YN), gadolinium nitride (GdN) and tantalum nitride (TaN), in combination with a silicon-containing composition and/or an aluminum-containing composition. In an exemplary embodiment, the first metal layer 131 has an average thickness of about 1 to about 100 Angstroms

[symbol]

The second metal layer 132 may be deposited on the first metal layer 131. The second metal layer 132 may be formed from a material having good thermal stability so that any chemical reaction that occurs between the first metal layer 131 and the third metal layer 133 can be controlled. In an exemplary embodiment, the second metal layer 132 may be formed from aluminum nitride (AlN). However, the second metal layer 132 may comprise one or more metal nitrides, wherein the metal element is selected from the group consisting of tungsten (W), molybdenum (Mo), titanium (Ti), tantalum (Ta), aluminum (Al), hafnium (Hf), lanthanum (La), gadolinium (Gd), yttrium (Y), praseodymium (Pr), dysprosium (Dy), erbium (Er), and zirconium (Zr). Alternatively, the second metal layer 132 may comprise one or more metal nitrides, wherein the metal element is selected from the group consisting of tungsten (W), molybdenum (No), titanium (Ti), tantalum (Ta), aluminum (Al), hafnium (Hf), lanthanum (La), gadolinium (Gd), yttrium (Y), praseodymium (Pr), dysprosium (Dy), erbium (Er), and zirconium (Zr), in combination with a silicon-containing composition and/or an aluminum-containing composition. In an exemplary embodiment, the second metal layer 132 has an average thickness of about 1 to about 100 Å.

The third metal layer 133 may be deposited on the second metal layer 132. In an exemplary embodiment, the third metal layer 133 is formed from hafnium nitride (HfN) However, the third metal layer 133 may comprise one or more metals and/or one or more metal nitrides, wherein the metal is selected from the group consisting of tungsten (W), molybdenum (Mo), titanium (Ti), tantalum (Ta), aluminum (Al), hafnium (Hf) and zirconium (Zr). Alternatively, the third metal layer 133 may be formed of one or more metals and/or one or more metal nitrides, wherein the metal is selected from the group consisting of tungsten (W), molybdenum (Mo), titanium (Ti), tantalum (Ta), aluminum (Al), hafnium (Hf) and zirconium (Zr), in combination with a silicon-containing composition and/or an aluminum-containing composition. In an exemplary embodiment, the third metal layer 133 has an average thickness of about 1 to about 1000 Å.

Like the gate oxide layer 120, the first metal layer 131, the second metal layer 132, and the third metal layer 133 of the gate electrode may independently be deposited by PVD, CVD, or epitaxy.

The material layer 140 has a good conductivity, and may be deposited oil the metal layers 130 so that the structure of the material layer 140 and the metal layers 130 can be used as a gate electrode. The material layer 140 may use one of poly silicon (Poly-Si), tungsten (W), tungsten nitride (WN), and tungsten silicide (WSi). For example, when being formed of poly-silicon (Poly-Si), the material layer 140 may be formed in a MIPS (Metal Inserted Poly-Si Stack) structure.

Hereinafter, the present invention will be explained in more detail with reference to the following examples. However these examples are given for the purpose of illustration and are not to be construed as limiting the scope of the invention.

Characteristics of exemplary embodiments of the semiconductor device according to the present invention will become more apparent by comparison with the other technologies. In the first comparative example, a gate electrode formed from a single metal layer and poly-Si were deposited on a gate oxide layer formed from HfSiO. The single metal layer was formed from TaN, and had a thickness of about 40

[symbol]

In the second comparative example, a gate electrode formed from a single metal layer (HfN) and poly-Si was deposited on a gate oxide layer formed from HfSiO. The thickness of the metal layer (HfN) was about 40

[symbol]

In the third comparative example, a gate electrode formed from three metal layers and poly-Si was deposited on a gate oxide layer formed from HfSiO. In this example, the first metal layer was formed from TaN and had a thickness of about 20 [symbol] , the second metal layer was formed from AlN and had a thickness of about 10 [symbol] , and the third metal layer was formed from TaN and had a thickness of about 20

[symbol]

The fourth example is an exemplary embodiment of a semiconductor device according to the present invention, in which a gate electrode formed from three metal layers and poly-Si was formed on a gate oxide layer formed from HfSiO. In this example, the first metal layer was formed from HfN, which has a common metal element as the gate oxide layer material. The first metal layer formed of HfN had a thickness of about 20 [symbol] , the second metal layer was formed from AlN and had a thickness of about 10 [symbol] , and the third metal layer was formed from TaN and had a thickness of about 20

[symbol]

The compositions of the first through fourth examples are listed as follows:

TABLE 1

| | Gate | 1st metal | 2nd metal | 3rd metal | |
|---|---|---|---|---|---|
| | Oxide | layer | layer | layer | Material |
| | Layer | (M1) | (M2) | (M3) | layer |
| 1st example | HfSiO | TaN (40 Å) | — | — | Poly-Si |
| 2nd example | | HfN (40 Å) | — | — | |
| 3rd example | | TaN (20 Å) | AlN | TaN (20 Å) | |
| | | | (10 Å) | | |
| 4th example | | HfN (20 Å) | AlN | TaN (20 Å) | |
| | | | (10 Å) | | |

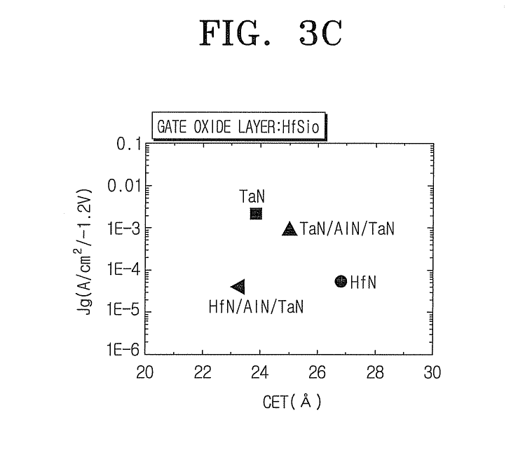

FIG. 3A is a graphical representation of the C-V characteristics of the semiconductor device according to the respective examples shown in Table 1. The vertical axis is the capacitance, and the horizontal axis is the level of voltage. The C-V characteristics of the semiconductor devices may be divided into accumulation area, depletion area, and inversion area according to the level of voltage; and among these areas, the operation of the semiconductor device is affected in the inversion area.

Compared to the first and the second examples which use a single metal layer, or to the third example which chooses a material for the first metal layer without considering the gate oxide layer, the fourth example, which is an exemplary semiconductor device according to the present invention, adopts a material for the first metal layer that has a common metal element as the gate oxide layer material, and provides a higher capacitance to the semiconductor device.

FIG. 3B is a graphical representation of the leakage current density-voltage characteristics for the semiconductor devices listed in Table 1. The vertical axis is leakage current density, and the horizontal axis is the level of voltage. As shown in FIG. 3B, by forming the first metal layer 131 according to the present invention, generation of an interface layer between the gate oxide layer 120 and the first metal layer 131 is reduced, and the leakage current density is reduced.

FIG. 3C is a graphical representation of the leakage current and CET characteristics at a certain voltage of the semiconductor devices listed in Table 1. As shown in FIG. 3C, by stacking a plurality of metal layers on one another, and forming one of them that contacts the gate oxide layer according to the present invention, the CET is improved and the leakage current density is reduced. As a result, improved insulation can be expected from the semiconductor device.

As explained above, according to the exemplary embodiments of the present invention, a gate electrode is formed by stacking a plurality of metal layers on the gate oxide layer, wherein the metal layer that contacts the gate oxide layer is formed from a material that has a common metal element with the material of the gate oxide layer. Accordingly, any reaction between the gate oxide layer and the metal layer is controlled, the CET is improved, and the leakage current is reduced. As a result, a semiconductor device having improved insulation can be provided.

Although the present invention has been described herein with reference to the foregoing exemplary embodiments, these exemplary embodiments do not serve to limit the scope of the present invention. Accordingly, it will be understood by those skilled in the art that various changes and modifications can be made within the spirit and scope of the present invention as defined by the appended claims.

What is claimed is:

1. A semiconductor device, comprising:
a substrate;
a gate oxide layer deposited on the substrate, and formed from a high-k dielectric material;
a first metal layer deposited on the gate oxide layer, and formed from a nitride of a metal of the high-k dielectric material of the gate oxide layer;
a second metal layer deposited on the first metal layer;
a third metal layer deposited on the second metal layer; and
a material layer deposited on the third metal layer, wherein the material layer taken together with the first, second, and third metal layers forms a gate electrode.

2. The semiconductor device of claim 1, wherein the gate oxide layer is formed from SiO₂ and/or a material having a dielectric constant greater than or equal to about 3.9.

3. The semiconductor device of claim 2, wherein the gate oxide layer further comprises a nitride.

4. The semiconductor device of claim 1, wherein the first metal layer is formed from one or more compositions selected from the group consisting of HfN, ZrN, AlN, TiN, LaN, YN, GdN and TaN.

5. The semiconductor device of claim 4, wherein the first metal further comprises a Si-containing composition or an Al-containing composition.

6. The semiconductor device of claim 1, wherein the second metal layer is formed from a metal nitride comprising one or more elements selected from the group consisting of W, Mo, Ti, Ta, Al, Hf, La, Gd, Y, Pr, Dy, Er, and Zr.

7. The semiconductor device of claim 6, wherein the second metal layer further comprises a Si-containing composition or an Al-containing composition.

8. The semiconductor device of claim 1, wherein the third metal layer is formed from a metal and/or a metal nitride comprising one or more elements selected from the group consisting of W, Mo, Ti, Ta, Al, Hf, and Zr.

9. The semiconductor device of claim 8, wherein the third metal layer further comprises a Si-containing composition or an Al-containing composition.

10. The semiconductor device of claim 1, wherein the gate oxide layer is formed from HfSiO and the first metal layer is formed from HfN.

11. The semiconductor device of claim 1, wherein the second metal layer is formed from AlN and the third metal layer is formed from TaN.

12. The semiconductor device of claim 1, wherein the first metal layer has an average thickness of about 1 Angstrom to about 100 Angstroms.

13. The semiconductor device of claim 1, wherein the second metal layer has an average thickness of about 1 Angstrom to about 100 Angstrom.

14. The semiconductor device of claim 1, wherein the third metal layer has an average thickness of about 1 Angstrom to about 1000 Angstroms.

15. The semiconductor device of claim 1, wherein the material layer deposited on the third metal layer is formed from one of polycrystalline silicon, W, WN and WSi.

16. A method, comprising:
depositing a gate oxide layer comprising a high-k dielectric on a substrate;
depositing a first metal layer on the gate oxide layer, wherein the first metal layer is formed from a nitride of a metal of the high-k dielectric material of the gate oxide layer;
depositing at least one more metal layer on the first metal layer; and
depositing a material layer on the at least one more metal layer, wherein the material layer taken together with the all of the metal layers forms a gate electrode.

17. The method of claim 16, wherein the depositing at least one more metal layer on the first metal layer comprises:
depositing a second metal layer on the first metal layer; and
depositing a third metal layer on the second metal layer.
